(19) United States
(12) Patent Application Publication
(10) Pub. No.: US 2025/0321252 A1
(43) Pub. Date: Oct. 16, 2025

(54) VOLTAGE DETECTION CIRCUIT

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Soya TANIGUCHI, Nisshin-shi (JP); Shotaro WADA, Nisshin-shi (JP); Yoshikazu FURUTA, Nisshin-shi (JP); Tomohiro NEZUKA, Nisshin-shi (JP)

(21) Appl. No.: 18/977,276

(22) Filed: Dec. 11, 2024

(30) Foreign Application Priority Data
Apr. 10, 2024 (JP) 2024-063565

(51) Int. Cl. G01R 19/155; G01R 19/25

(52) U.S. Cl. CPC G01R 19/155; G01R 19/2503

(57) ABSTRACT

A voltage detection circuit includes a modulation signal generator, an AD converter, a current source, a differentiator, a multiplier, and an integrator. The modulation signal generator generates a modulation signal. The AD converter converts a voltage applied between a first input wiring and a second input wiring into a digital value. The current source supplies a first current to the first input wiring and supplies a second current to the second input wiring. The first current changes based on the modulation signal, and the second current changes based on the modulation signal. The differentiator outputs a value acquired by differentiating an output value of the AD converter. The multiplier multiplies an output value of the differentiator by a value that varies positively and negatively according to the modulation signal. The integrator integrates an output value of the multiplier.

### CROSS REFERENCE TO RELATED APPLICATION

This application is based on Japanese Patent Application No. 2024-063565 filed on Apr. 10, 2024, the disclosure of which is incorporated herein by reference.

### TECHNICAL FIELD

The present disclosure relates to a voltage detection circuit.

### BACKGROUND

A voltage detection circuit may include an AD converter (analog-to-digital converter) and a frequency signal generation circuit. The frequency signal generation circuit may be connected to an input terminal of the AD converter via a resistor. The frequency signal generation circuit may generate a pulse voltage at a reference frequency. When the input terminal of the AD converter is disconnected from a detection target device, a potential of the input terminal of the AD converter may fluctuate at the reference frequency. This voltage detection circuit may detect a disconnection by detecting a fluctuating potential synchronized with the reference frequency in the output value of the AD converter.

### SUMMARY

The present disclosure describes a voltage detection circuit including a modulation signal generator, an AD converter, a current source, a differentiator, a multiplier, and an integrator.

### BRIEF DESCRIPTION OF DRAWINGS

FIG. 1 is a circuit diagram of a voltage detection circuit according to a first embodiment.

FIG. 2 is a graph that illustrates a normal operation in the first embodiment.

FIG. 3 is a graph that illustrates an event of a disconnection in the first embodiment.

FIG. 4 is a circuit diagram of a voltage detection circuit according to a second embodiment.

FIG. 5 is a graph that illustrates a normal operation in the second embodiment.

FIG. 6 is a graph that illustrates an event of a disconnection in the second embodiment.

FIG. 7 is a circuit diagram of a voltage detection circuit according to a third embodiment.

FIG. 8 is a circuit diagram of a voltage detection circuit according to a fourth embodiment.

FIG. 9 is a graph that illustrates an event of a disconnection in the fourth embodiment.

FIG. 10 is a circuit diagram of a voltage detection circuit according to a fifth embodiment.

FIG. 11 is a circuit diagram of a voltage detection circuit according to a sixth embodiment.

FIG. 12 is a circuit diagram of a modulation signal generator according to a seventh embodiment.

FIG. 13 is a circuit diagram of a disconnection detection circuit in a modified example.

FIG. 14 is a circuit diagram of a disconnection detection circuit in another modified example.

### DETAILED DESCRIPTION

In a comparative example related to a voltage detection circuit, disconnection is detected when the amplitude of a fluctuating potential (i.e., the fluctuating potential synchronized with the reference frequency) output by an AD converter exceeds a reference value, so it may be necessary for a frequency voltage generation circuit to generate a pulse voltage with a large amplitude. When a pulse voltage with such a large amplitude is applied to the input terminal of the AD converter, the offset voltage increases. Thus, a decrease in voltage detection accuracy may occur.

According to an aspect of the present disclosure, a voltage detection circuit includes a modulation signal generator, an AD converter, a current source, a differentiator, a multiplier, and an integrator. The modulation signal generator generates a modulation signal. The AD converter converts a voltage applied between a first input wiring and a second input wiring into a digital value. The current source supplies a first current to the first input wiring and supplies a second current to the second input wiring. The first current varies based on the modulation signal, and the second current varies based on the modulation signal. The differentiator outputs a value acquired by differentiating an output value of the AD converter. The multiplier multiplies an output value of the differentiator by a value that varies positively and negatively according to the modulation signal. The integrator integrates an output value of the multiplier.

In this voltage detection circuit, the first input wiring and the second input wiring are adapted to be connected to a voltage detection target device. The current source supplies the first current that varies according to the modulation signal to the first input wiring and the second current that varies according to the modulation signal to the second input wiring.

If there is no disconnection in the first input wiring and the second input wiring, the first current and the second current flow to an external circuit. In this case, the voltage generated between the first input wiring and the second input wiring due to the first current and the second current is small. In other words, the voltage between the first and second input wirings contains almost no voltage components synchronized with the modulation signal. In this case, the output value of the differentiator (i.e., the value obtained by differentiating the output value of the AD converter) contains very little voltage component synchronized with the modulation signal, resulting in a relatively flat waveform for the output value of the differentiator. Therefore, the output value of the multiplier (i.e., the value obtained by multiplying the output value of the differentiator by the value that varies positively and negatively according to the modulation signal) will be a value that varies positively and negatively. As a result, the output value of the integrator (i.e., the value obtained by integrating the output value of the multiplier) is maintained at a low value.

If a disconnection occurs in either the first input wiring or the second input wiring, the disconnected input wiring will be charged by the first current or the second current, causing the potential of the disconnected input wiring to rise. At this time, the potential of the disconnected input wiring rises in a step-like manner in synchronization with the modulation signal. In this case, the output value of the differentiator (i.e., the value obtained by differentiating the output value of the AD converter) fluctuates in synchronization with the modulation signal. Therefore, when the output value of the differentiator, which fluctuates in synchronization with the modulation signal, is multiplied by the value that varies positively and negatively according to the modulation signal in the multiplier, the output value of the multiplier becomes a signal that fluctuates biasedly towards positive or negative values (for example, a signal that fluctuates between zero and positive values or between zero and negative values). As a result, the absolute value of the output of the integrator (i.e., the value obtained by integrating the output of the multiplier) increases over time. In the present disclosure, zero may also be written as “0” for convenience.

As described above, the output value of the integrator varies depending on the presence or absence of the disconnection. Therefore, the presence or absence of the disconnection can be detected based on the output value of the integrator. Additionally, in this voltage detection circuit, since the first current is supplied to the first input wiring and the second current is supplied to the second input wiring, the offset voltage caused by the first and second currents is small, allowing for accurate voltage detection. Furthermore, in the event of the disconnection, the integrator integrates the variation in potential caused by the disconnection, allowing the detection of the disconnection even if the voltage generated between the input wirings is not very large. In this way, this voltage detection circuit not only enables high-precision voltage detection but also allows for the reliable detection of the disconnection.

### First Embodiment

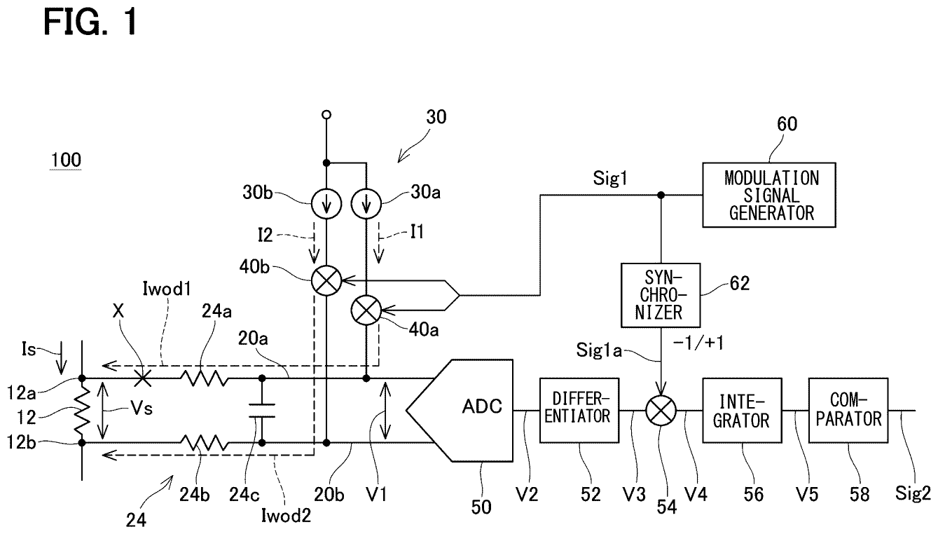

A voltage detection circuit 100 according to a first embodiment shown in FIG. 1 is connected to a shunt resistor 12. The shunt resistor 12 is connected to an external circuit (not shown). A current Is flows to an external circuit through the shunt resistor 12. The voltage detection circuit 100 detects the current Is by detecting the voltage Vs generated at the shunt resistor 12.

The voltage detection circuit 100 includes a first input wiring 20a, a second input wiring 20b, and an anti-aliasing filter 24 (hereinafter referred to as AAF 24). The first input wiring 20a and the second input wiring 20b are connected to the shunt resistor 12 via the AAF 24. The AAF 24 has a first resistor 24a, a second resistor 24b, and a capacitor 24c. The first input wiring 20a is connected to one terminal 12a of the shunt resistor 12 via the first resistor 24a. The second input wiring 20b is connected to the other terminal 12b of the shunt resistor 12 via the second resistor 24b. Therefore, the shunt resistor 12 is connected between the first input wiring 20a and the second input wiring 20b via the first resistor 24a and the second resistor 24b. The electrical resistance R1 of the first resistor 24a is approximately equal to the electrical resistance R2 of the second resistor 24b. The electrical resistance of the shunt resistor 12 is much smaller than the electrical resistances R1 and R2. The capacitor 24c is connected between the first input wiring 20a and the second input wiring 20b.

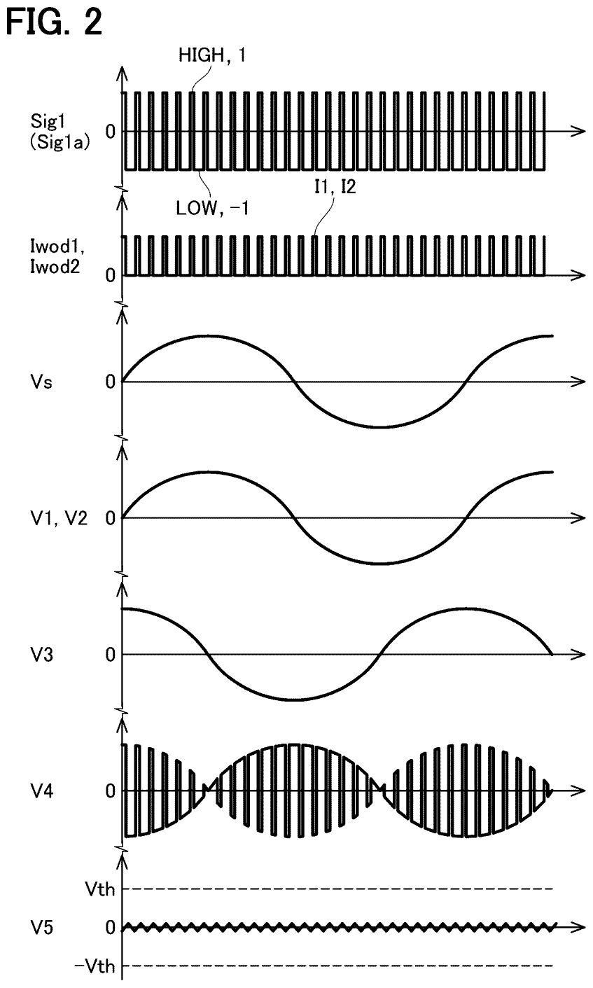

The voltage detection circuit 100 includes a modulation signal generator 60 and a synchronizer 62. The modulation signal generator 60 outputs a pulse signal Sig1. As shown in FIG. 2, the signal Sig1 is a pulse signal that alternates between the HIGH value and the LOW value at a frequency fc. The signal Sig1 is provided to the synchronizer 62. The synchronizer 62 outputs a pulse signal Sig1a that is synchronized with the pulse signal Sig1. The pulse signal Sigla is a digital signal that becomes 1 when the pulse signal Sig1 is HIGH and becomes −1 when the pulse signal Sig1 is LOW. In other words, the pulse signal Sigla has the same waveform as the pulse signal Sig1.

The voltage detection circuit 100 includes a current source 30. The current source 30 includes a first constant current source 30a, a second constant current source 30b, a switch circuit 40a, and a switch circuit 40b.

The first constant current source 30a generates a constant DC current I1. The first constant current source 30a is connected to the first input wiring 20a via the switch circuit 40a. When the switch circuit 40a is turned on, the current I1 is supplied from the first constant current source 30a to the first input wiring 20a. When the switch circuit 40a is turned off, the supply of the current I1 from the first constant current source 30a to the first input wiring 20a is stopped. The switch circuit 40a receives the signal Sig1. The switch circuit 40a turns on and off in synchronization with the signal Sig1. Therefore, as shown in FIG. 2, the current Iwod1 flowing through the first input wiring 20a becomes a pulse current synchronized with the signal Sig1. As shown in FIG. 1, the current Iwod1 flows to the external circuit through the first resistor 24a.

The second constant current source 30b generates a constant DC current I2. The current I2 is equal to the current I1. The second constant current source 30b is connected to the second input wiring 20b via the switch circuit 40b. When the switch circuit 40b is turned on, the current I2 is supplied from the second constant current source 30b to the second input wiring 20b. When the switch circuit 40b is turned off, the supply of current I2 from the second constant current source 30b to the second input wiring 20b is stopped. The switch circuit 40b receives the signal Sig1. The switch circuit 40b turns on and off in response to the signal Sig1. Therefore, as shown in FIG. 2, the current Iwod2 flowing through the second input wiring 20b becomes a pulse current synchronized with the signal Sig1. In other words, the waveform of the current Iwod2 matches the waveform of the current Iwod1. As shown in FIG. 1, the current Iwod2 flows to the external circuit through the second resistor 24b.

Since the current Iwod1 flows through the first resistor 24a, the potential of the first input wiring 20a becomes higher than the potential of the terminal 12a of the shunt resistor 12 by a voltage Va (Va=R1×Iwod1). Furthermore, since the current Iwod2 flows through the second resistor 24b, the potential of the second input wiring 20b becomes higher than the potential of the terminal 12b of the shunt resistor 12 by a voltage Vb (Vb=R2×Iwod2). If the electrical resistance R1 matches the electrical resistance R2 and the current Iwod1 matches the current Iwod2, then Va will be equal to Vb. However, in reality, there are discrepancies between the electrical resistance R1 and the electrical resistance R2, as well as between the current Iwod1 and the current Iwod2. Therefore, the voltage Va and the voltage Vb do not match. Therefore, a voltage V1 is applied between the first input wiring 20a and the second input wiring 20b, where V1=Vs+ΔV (where ΔV=Va−Vb). In other words, the voltage V1 will be offset by a voltage ΔV relative to the target voltage Vs being detected. In the following, the voltage ΔV is referred to as the offset voltage ΔV.

The voltage detection circuit 100 includes an AD converter 50 (hereinafter referred to as ADC 50). The ADC 50 is connected to the first input wiring 20a and the second input wiring 20b. The ADC 50 outputs a signal that converts the voltage V1 between the first input wiring 20a and the second input wiring 20b into a digital value. Hereinafter, the voltage indicated by the digital signal output by the ADC 50 will be referred to as voltage V2. The voltage V2 is used as the detected value of the voltage Vs. For example, the digital signal output by the ADC 50 is provided to a control circuit (not shown) via a digital low-pass filter or the like, and the control circuit performs control in accordance with the voltage V2.

The voltage detection circuit 100 functions as a disconnection detection circuit and includes a differentiator 52, a multiplier 54, an integrator 56, and a comparator 58.

The differentiator 52 differentiates the voltage V2 output by the ADC 50 with respect to time. Therefore, the voltage V3 indicated by the output signal of the differentiator 52 represents the rate of change of the voltage V2 (i.e., the variation in voltage per unit time).

The multiplier 54 multiplies the voltage V3 output by the differentiator 52 by the signal Sigla output by the synchronizer 62. Therefore, the voltage V4 output by the multiplier 54 matches the voltage V3 when the signal Sigla is 1, and matches the voltage V3 with its polarity reversed when the signal Sigla is −1.

The integrator 56 integrates the voltage V4 output by the multiplier 54 with respect to time.

The comparator 58 determines whether the voltage V5 output by the integrator 56 is within the range that is lower than the threshold Vth and higher than the threshold-Vth. The range between the threshold Vth and the threshold-Vth is the range within which the voltage V5 can fall if there is no disconnection in the input wiring (i.e., the normal range of the voltage V5). Therefore, the output signal Sig2 from the comparator 58 indicates whether there is a disconnection in the input wiring or not.

FIG. 2 illustrates the changes in various values during the normal operation of the voltage detection circuit 100. As described above, signals Sig1 and Sigla are pulse signals that vary at a constant frequency fc. Since the common signal Sig1 is provided to the switch circuits 40a and 40b, the currents Iwod1 and Iwod2 both become pulse signals with the same waveform as the signal Sig1. The current Iwod1 fluctuates between the current I1 and zero, while the current Iwod2 fluctuates between the current I2 and zero. Additionally, the voltage Vs being detected fluctuates at a frequency much lower than the frequency fc of the signal Sig1. As mentioned above, the voltage V1 between the first input wiring 20a and the second input wiring 20b satisfies the relationship V1=Vs+ΔV. Since the offset voltage ΔV is small, the voltage V1 is almost identical to the voltage Vs in FIG. 2. The voltage V2 output by the ADC 50 is approximately equal to the voltage V1. Since the differentiator 52 differentiates the voltage V2 with respect to time, the voltage V3 output by the differentiator 52 represents the rate of change of the voltage V2. The multiplier 54 outputs the voltage V4, which is the result of multiplying the signal Sigla, fluctuating between 1 and −1 at the frequency fc, by the voltage V3. As shown in FIG. 2, during the period when the signal Sigla is 1, the voltage V4 matches the voltage V3, and during the period when the signal Sigla is −1, the voltage V4 matches the voltage V3 with its polarity inverted. Therefore, the voltage V4 fluctuates periodically between positive and negative values. The integrator 56 outputs the voltage V5, which is the integrated value of the voltage V4 output by the multiplier 54. Since the voltage V4 fluctuates periodically between positive and negative values, the voltage V5 will repeatedly increase and decrease periodically. As a result, the voltage V5 is maintained around a value close to zero. Therefore, the voltage V5 is maintained at a value lower than the threshold Vth and higher than the negative threshold-Vth. Therefore, the comparator 58 outputs a value indicating that the voltage V5 is within the normal range.

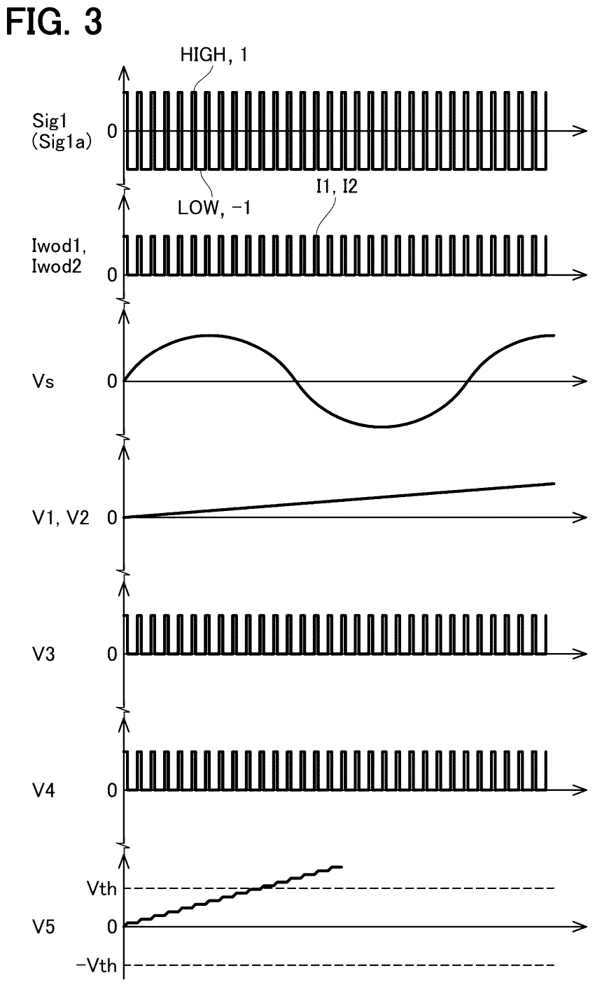

FIG. 3 shows the changes in each value when a disconnection occurs at point X in FIG. 1 (i.e., when the first input wiring 20a is disconnected from the terminal 12a). In this case, the voltage Vs is not applied between the first input wiring 20a and the second input wiring 20b. Additionally, the current Iwod1 ceases to flow from the first input wiring 20a to the terminal 12a. Therefore, the first input wiring 20a is charged by the current Iwod1, and as shown in FIG. 3, the voltage V1 rises independently of the voltage Vs. For example, the capacitor 24c is charged by the current Iwod1, causing the voltage V1 to rise. The voltage V2 rises in a similar manner to the voltage V1. The voltage V3 output by the differentiator 52 represents the rate of change of the voltage V2. During the period when the current Iwod1 is flowing, the voltages V1 and V2 increase, and during the period when the current Iwod1 is zero, the voltages V1 and V2 do not increase. Therefore, the voltage V3 output by the differentiator 52 has the same waveform as the current Iwod1. In other words, the voltage V3 fluctuates between a positive value and zero at the frequency fc. The multiplier 54 outputs the value obtained by multiplying the signal Sigla by the voltage V3 as the voltage V4. During the period when the signal Sigla is 1, since the voltage V3 is a positive value, the voltage V4 will also be a positive value. During the period when the signal Sigla is −1, since the voltage V3 is zero, the voltage V4 will be zero. Therefore, the voltage V4, similar to the voltage V3, fluctuates between positive values and zero at the frequency fc. The integrator 56 integrates the voltage V4. Since the voltage V4 fluctuates between positive values and zero, the voltage V5 output by the integrator 56 increases in a stepwise manner over time. Therefore, at a predetermined timing, the voltage V5 exceeds the threshold value Vth. Then, the comparator 58 outputs a signal indicating that the voltage V5 is an abnormal value. Therefore, the output value of the comparator 58 can be used to detect the disconnection.

In the event of the disconnection in the second input wiring 20b, the current Iwod2 charges the second input wiring 20b, causing its potential to rise. As a result, the voltages V1 and V2 decrease over time, and the voltages V3 and V4 fluctuate between negative values and zero. In this case, the voltage V5 decreases over time and falls below the threshold-Vth at a predetermined timing. Therefore, the comparator 58 outputs a signal indicating that the voltage V5 is at an abnormal value. Therefore, the output value of the comparator 58 can be used to detect the disconnection.

As described above, in the voltage detection circuit 100 according to the first embodiment, the voltage V5 output by the integrator 56 changes depending on the presence of the disconnection. Therefore, it is possible to detect a disconnection based on the voltage V5 output by the integrator 56. Additionally, in the voltage detection circuit according to the first embodiment, synchronized currents Iwod1 and Iwod2 are applied to the first input wiring 20a and the second input wiring 20b, respectively, resulting in a small offset voltage ΔV. Therefore, during the normal operation, the voltage Vs can be accurately detected.

In the voltage detection circuit 100 of the first embodiment, since the voltage V2 increases or decreases in the event of the disconnection, it is also possible to detect the disconnection when the voltage V2 falls outside the normal range. However, since the normal range of voltage V2 is wide, it takes time for the voltage V2 to change to a value outside the normal range. In contrast, in the voltage detection circuit 100 according to the first embodiment, since the fluctuating component synchronized with the signal Sig1 can be extracted as the voltage V4 from the voltage V2, a disconnection can be detected in a short time by integrating the voltage V4.

In addition, in the voltage detection circuit 100 according to the first embodiment, the integrator 56 detects the disconnection by integrating the voltage V4 over multiple cycles of the signal Sig1 with the frequency fc. Therefore, even if the voltage Vs itself oscillates for a short time at a frequency close to fc due to noise or other factors, the erroneous detection of such oscillations of voltage Vs as the disconnection is suppressed. Thus, in the voltage detection circuit 100 according to the first embodiment, erroneous detection of the disconnection is less likely to occur.

### Second Embodiment

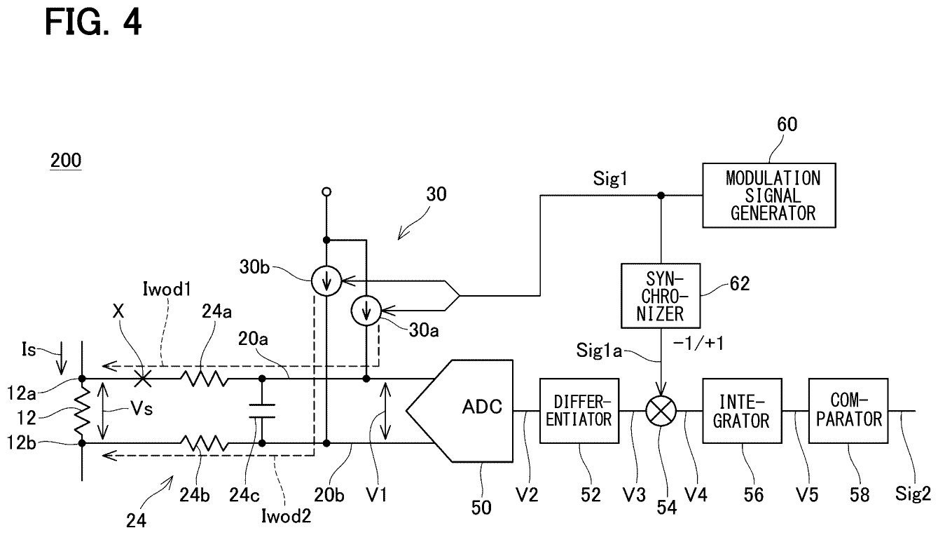

In a voltage detection circuit 200 according to a second embodiment shown in FIG. 4, the configurations of the current source 30 and the modulation signal generator 60 differ from those in the first embodiment. Other configurations of the voltage detection circuit 200 in the second embodiment are the same as those of the first embodiment.

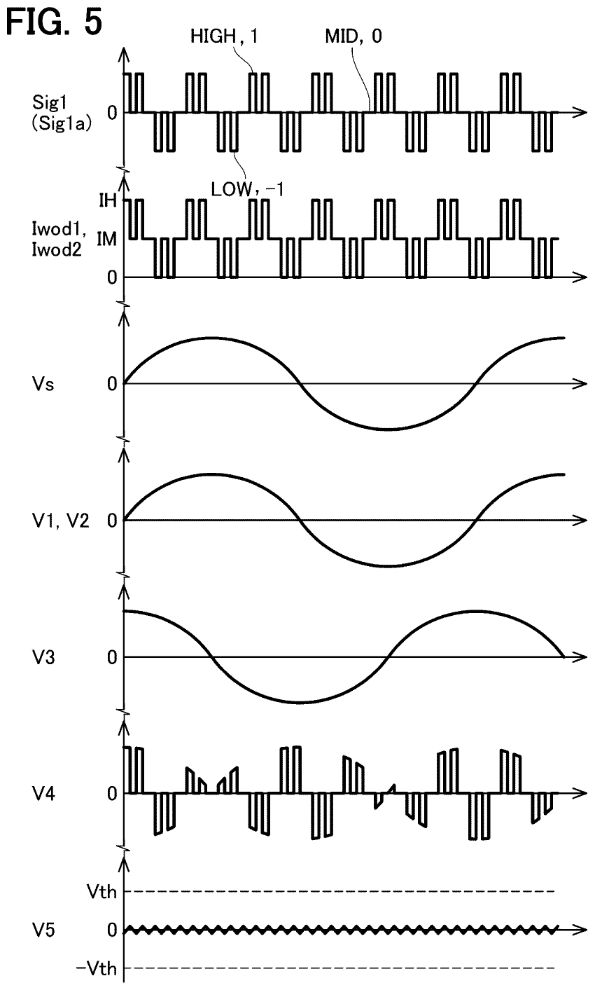

In the second embodiment, as shown in FIG. 5, the signal Sig1 output by the modulation signal generator 60 varies between the values HIGH, LOW, and the intermediate value MID. The signal Sig1 output by the modulation signal generator 60 is a pulse signal that combines a pulse signal with a frequency fa and a pulse signal with a frequency fb. Additionally, the synchronizer 62 sets the signal Sigla to 0 when the signal Sig1 is at the MID value. In other words, the signal Sigla varies in three levels: 1, 0, and −1.

In the second embodiment, the current source 30 does not have the switch circuits 40a and 40b. In other words, the first constant current source 30a is directly connected to the first input wiring 20a, and the second constant current source 30b is directly connected to the second input wiring 20b. In other words, in the second embodiment, the current output by the first constant current source 30a flows into the first input wiring 20a as the current Iwod1, and the current output by the second constant current source 30b flows into the second input wiring 20b as the current Iwod2. Additionally, in the second embodiment, the signal Sig1 is input to both the first constant current source 30a and the second constant current source 30b. The first constant current source 30a and the second constant current source 30b change the magnitude of the output current in synchronization with the signal Sig1. As shown in FIG. 5, the first constant current source 30a outputs a pulse current synchronized with the signal Sig1 as the current Iwod1, and the second constant current source 30b outputs a pulse current synchronized with the signal Sig1 as the current Iwod2. More specifically, when the signal Sig1 is at the HIGH value, the currents Iwod1 and Iwod2 become the high current IH; when the signal Sig1 is at the MID value, currents Iwod1 and Iwod2 become the intermediate level current IM; and when the signal Sig1 is at the LOW value, the currents Iwod1 and Iwod2 become zero.

In the second embodiment, during the normal operation, as shown in FIG. 5, when the signal Sigla is 1, the voltage V4 matches the voltage V3; when the signal Sigla is 0, the voltage V4 becomes 0; and when the signal Sigla is −1, the voltage V4 matches the value of the voltage V3 with its polarity inverted. Therefore, the voltage V4 periodically changes positively and negatively, and the voltage V5, which is the integrated value of voltage V4, is maintained around 0 V. Therefore, the voltage V5 is maintained within the normal range.

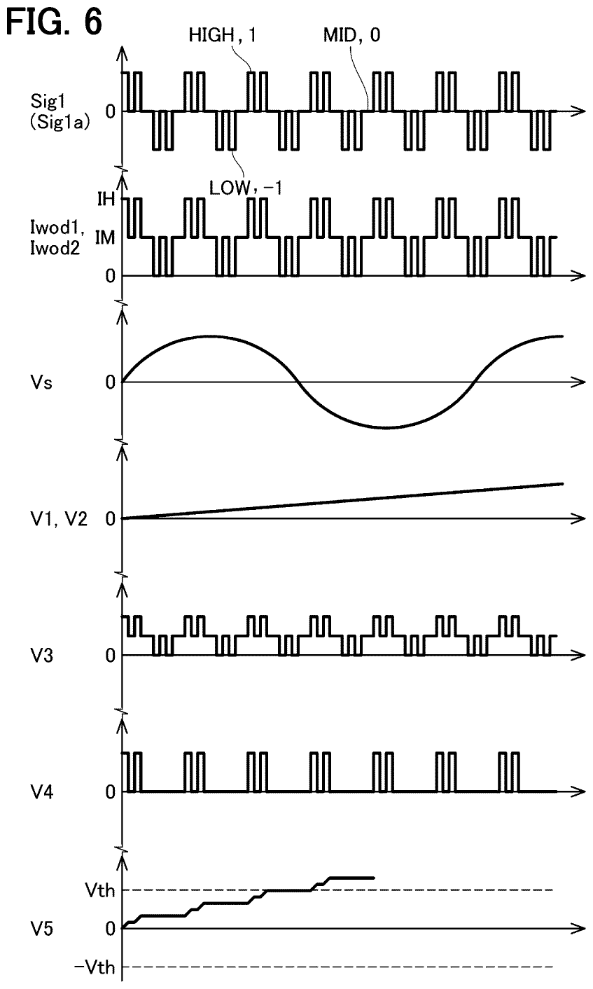

If the disconnection occurs in the first input wiring 20a, as shown in FIG. 6, the first input wiring 20a is charged by the current Iwod1, causing the voltages V1 and V2 to increase. Therefore, the voltage V3 will have a waveform that is approximately the same as that of the current Iwod1. Therefore, during the period when the signal Sigla is 1, the voltage V4 becomes a positive value, and during the period when the signal Sigla is 0, the voltage V4 becomes 0. Additionally, during the period when the signal Sigla is −1, since the voltage V3 is 0, the voltage V4 also becomes 0. In other words, the voltage V4 fluctuates between a positive value and 0. Therefore, the voltage V5, which is the integrated value of the voltage V4, increases over time. Therefore, when the voltage V5 exceeds the threshold Vth, the comparator 58 outputs a signal indicating the disconnection. In addition, if the disconnection occurs in the second input wiring 20b, the voltage V5 falls below the threshold-Vth, causing the comparator 58 to output a signal indicating the disconnection.

Thus, in the second embodiment, since the voltage V5 deviates from the normal range in the event of the disconnection, it is possible to detect the disconnection. Furthermore, in the second embodiment, since the signal Sig1 has multiple frequency components, false detection of disconnection due to the oscillation of the voltage Vs can be more effectively suppressed.

### Third Embodiment

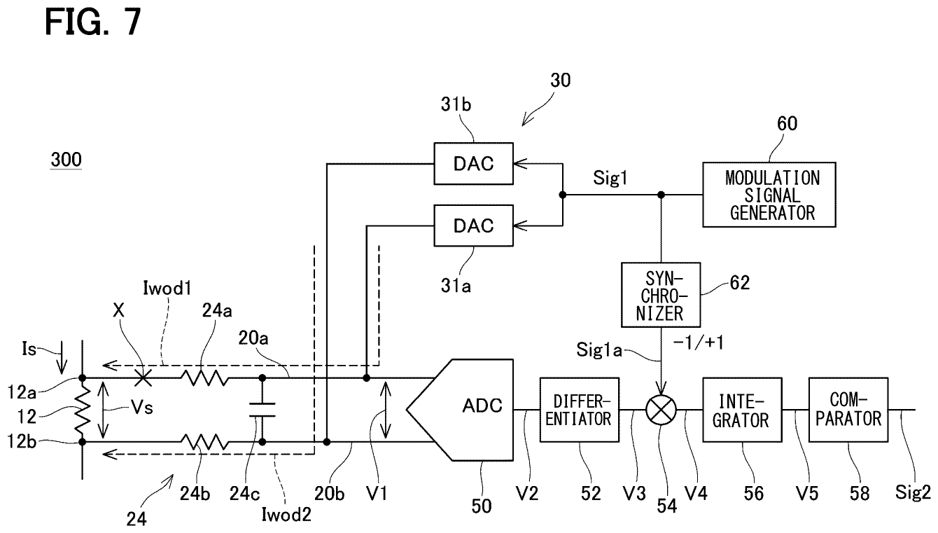

In a voltage detection circuit 300 according to a third embodiment shown in FIG. 7, the configuration of the current source 30 is different from that in the second embodiment. Other configurations of the voltage detection circuit 300 in the third embodiment are the same as those of the second embodiment.

In the third embodiment, the current source 30 includes a first DA converter (digital-to-analog converter) 31a (hereinafter referred to as the first DAC 31a) instead of the first constant current source 30a, and a second DA converter 31b (hereinafter referred to as the second DAC 31b) instead of the second constant current source 30b. The signal Sig1 is provided to both the first DAC 31a and the second DAC 31b. The first DAC 31a outputs the same current Iwod1 as in the second embodiment (that is, the current Iwod1 that changes in three stages: current IH, current IM, and 0) in synchronization with the signal Sig1. The second DAC 31b outputs the same current Iwod2 as in the second embodiment 2 (that is, the current Iwod2 that changes in three stages: current IH, current IM, and 0) in synchronization with the signal Sig1. Therefore, in the third embodiment, it is also possible to detect the disconnection in the same manner as in the second embodiment.

### Fourth Embodiment

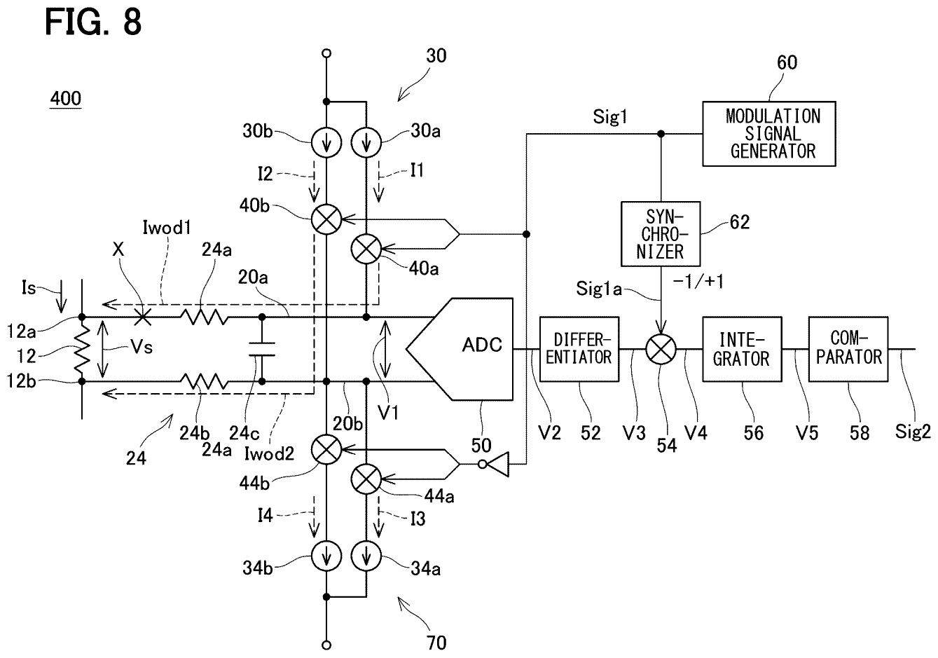

A voltage detection circuit 400 according to a fourth embodiment, shown in FIG. 8, includes a current generation circuit 70. The current generation circuit 70 includes a third constant current source 34a, a fourth constant current source 34b, a switch circuit 44a, and a switch circuit 44b. Other configurations of the fourth embodiment are the same as those of the first embodiment.

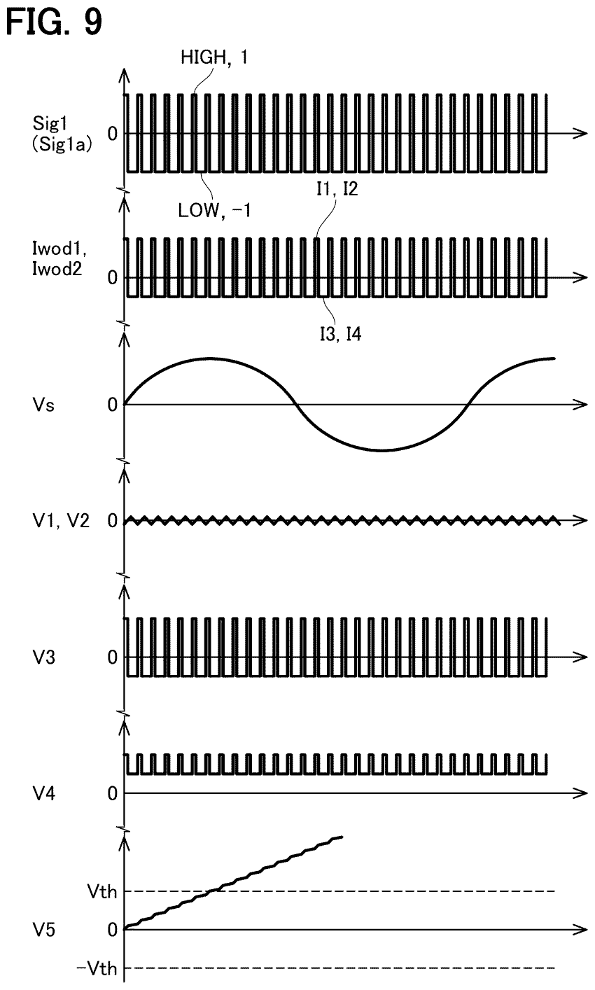

The third constant current source 34a generates a constant DC current I3. The third constant current source 34a is connected to the first input wiring 20a via the switch circuit 44a. When the switch circuit 44a is turned on, the current I3 flows from the first input wiring 20a to the third constant current source 34a. That is, the current I3 is drawn from the first input wiring 20a. When the switch circuit 44a is turned off, the current I3 stops flowing. The current Iwod1 flowing through the first input wiring 20a is the value obtained by subtracting the current I3 from the current I1. The switch circuit 44a receives a signal that is the inverted signal of the signal Sig1 (hereinafter referred to as the inverted signal). The switch circuit 44a turns on and off in synchronization with the inverted signal. Therefore, when the current I1 is stopped, the current I3 flows; and when the current I1 is flowing, the current I3 stops. Therefore, as shown in FIG. 9, the current Iwod1 becomes a pulse current that fluctuates between the positive value I1 and the negative value I3. The currents I1 and I3 are set so that the average value of the current Iwod1 becomes approximately zero. In FIG. 9, since the on-duty cycle of the current Iwod1 is 50% or less, the current I1 is greater than the current I3.

The fourth constant current source 34b generates a constant DC current I4. The fourth constant current source 34b is connected to the second input wiring 20b via the switch circuit 44b. When the switch circuit 44b is turned on, the current I4 flows from the second input wiring 20b to the fourth constant current source 34b. In other words, the current I4 is drawn from the second input wiring 20b. When the switch circuit 44b is turned off, the current I4 stops flowing. The value obtained by subtracting the current I4 from the current I2 becomes the current Iwod2 that flows through the second input wiring 20b. An inverted signal, which is the inversion of the signal Sig1, is provided to the switch circuit 44b. The switch circuit 44b turns on and off in synchronization with the inverted signal. Therefore, when the current I2 stops flowing, the current I4 flows; and when the current I2 flows, the current I4 stops flowing. Thus, the current Iwod2 becomes a pulsed current that fluctuates between the positive value I2 and the negative value I4, as shown in FIG. 9. The currents I2 and I4 are set such that the average value of the current Iwod2 becomes approximately zero.

Even in the normal operation of the fourth embodiment, since the currents Iwod1 and Iwod2 are approximately equal, the voltages Vs, V1, V2, V3, V4, and V5 vary in the same manner as in the first embodiment (i.e., as shown in FIG. 2). Therefore, even in the normal operation of the fourth embodiment, the voltage Vs can be detected. In particular, in the fourth embodiment, since the average value of the current Iwod1 and the average value of the current Iwod2 are approximately zero, the offset voltage ΔV is very small. Therefore, the voltage Vs can be detected more accurately.

Additionally, in the fourth embodiment, if the first input wiring 20a is disconnected, the first input wiring 20a is charged during the period when the current I1 is flowing, while the second input wiring 20b is discharged during the period when the current I3 is flowing. Therefore, as shown in FIG. 9, the voltages V1 and V2 remain approximately constant. Additionally, the voltage V3 exhibits the same waveform as the current Iwod1. That is, during the period when the current I1 is flowing, the voltage V3 takes on a positive value, and during the period when the current I3 is flowing, the voltage V3 takes on a negative value. In other words, during the period when the signal Sigla is 1, the voltage V3 takes on a positive value, and during the period when the signal Sigla is −1, the voltage V3 takes on a negative value. Therefore, the voltage V4 output by the multiplier 54 is always a positive value. Consequently, the voltage V5 output by the integrator 56 increases and exceeds the threshold value Vth, enabling the comparator 58 to detect an open circuit. Additionally, although not illustrated, if the second input wiring 20b is disconnected in the fourth embodiment, the voltage V4 will always be a negative value. Therefore, the voltage V5 decreases and falls below the threshold-Vth, enabling the comparator 58 to detect the disconnection. As described above, the disconnection may be detected in the fourth embodiment.

### Fifth Embodiment

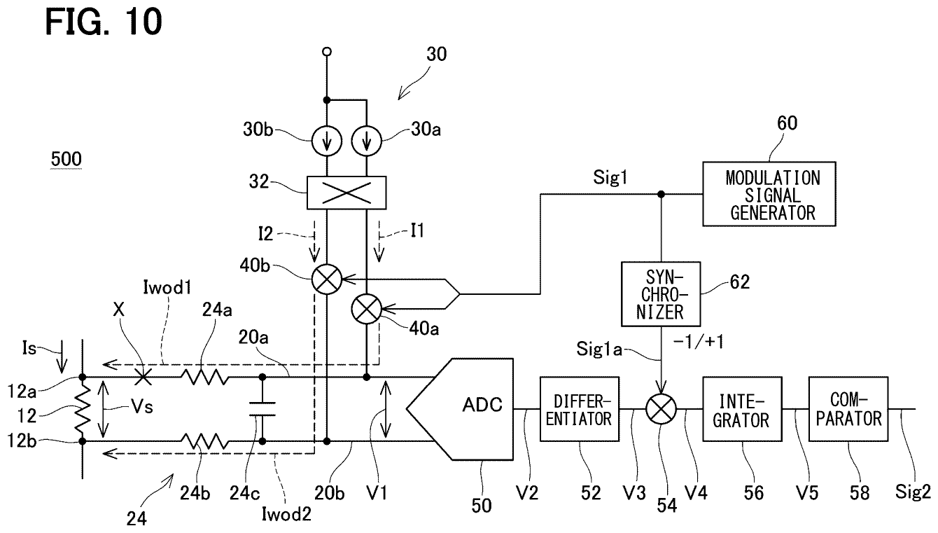

In a voltage detection circuit 500 according to a fifth embodiment shown in FIG. 10, the configuration of the current source 30 differs from that in the first embodiment. Other configurations of the voltage detection circuit 500 in the fifth embodiment are the same as those of the first embodiment.

In the fifth embodiment, the current source 30 includes a chopper circuit 32. The chopper circuit 32 is connected to the first constant current source 30a, the second constant current source 30b, the switch circuit 40a, and the switch circuit 40b. The chopper circuit 32 alternates the mutual connection state between the first constant current source 30a, the second constant current source 30b, the switch circuit 40a, and the switch circuit 40b between the first connection state and the second connection state at a predetermined frequency. In the first connection state, the first constant current source 30a is connected to the switch circuit 40a, and the second constant current source 30b is connected to the switch circuit 40b. In the first connection state, current Iwod1 fluctuates between current I1 and zero and current Iwod2 fluctuates between current I2 and zero. In the second connection state, the first constant current source 30a is connected to the switch circuit 40b, and the second constant current source 30b is connected to the switch circuit 40a. In the second connection state, the current Iwod1 fluctuates between the current I2 and zero, while the current Iwod2 fluctuates between the current I1 and zero. In this way, by alternately switching the paths of current I1 and current I2, it is possible to suppress the offset voltage ΔV that arises due to the difference between current Iwod1 and current Iwod2. Therefore, according to the voltage detection circuit 500, it is possible to detect the voltage Vs more accurately.

### Sixth Embodiment

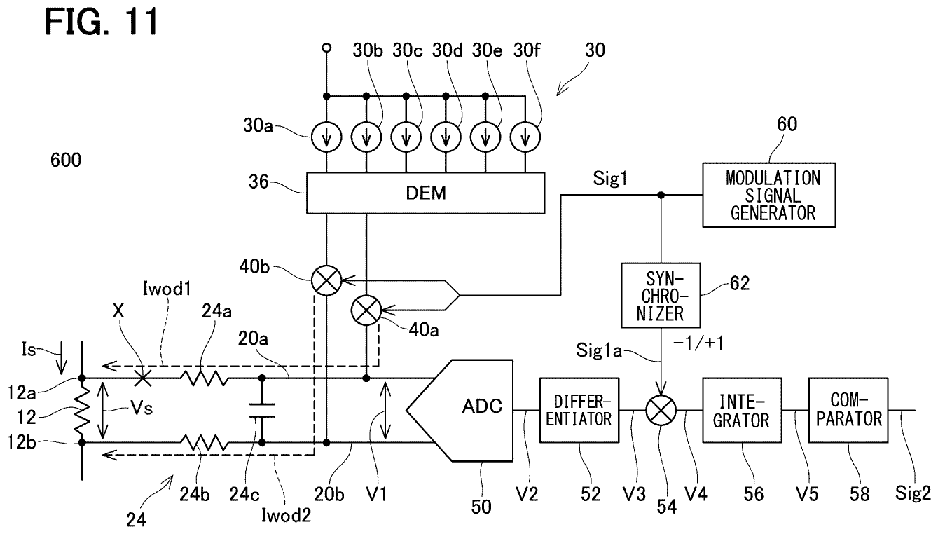

In a voltage detection circuit 600 according to the sixth embodiment shown in FIG. 11, the configuration of the current source 30 differs from that in the first embodiment. Other configurations of the voltage detection circuit 600 in the sixth embodiment are the same as those of the first embodiment.

In the sixth embodiment, the current source 30 includes six constant current sources 30a to 30f and a DEM (Dynamic Element Matching) 36. Each of the constant current sources 30a to 30f generates an equal current. However, there may be errors among the currents generated by the constant current sources 30a to 30f. The DEM 36 is connected to the constant current sources 30a to 30f, switch circuit 40a, and switch circuit 40b. The DEM 36 connects three selected constant current sources (hereinafter referred to as the first group of constant current sources) from the constant current sources 30a to 30f to switch circuit 40a, and connects the remaining three constant current sources (hereinafter referred to as the second group of constant current sources) to switch circuit 40b. Therefore, when switch circuit 40a is turned on, the current supplied from the three constant current sources of the first group flows into the first input wiring 20a as the current Iwod1, and when switch circuit 40b is turned on, the current supplied from the three constant current sources of the second group flows into the second input wiring 20b as the current Iwod2. The DEM 36 repeatedly changes the combination of the constant current sources in the first group and the combination of the constant current sources in the second group at a predetermined frequency. In this way, by periodically changing the combination of constant current sources that supply the current Iwod1 and the combination of constant current sources that supply the current Iwod2, it is possible to suppress the offset voltage that arises due to the difference between the current Iwod1 and the current Iwod2. Therefore, according to the voltage detection circuit 600, the voltage Vs can be detected more accurately.

### Seventh Embodiment

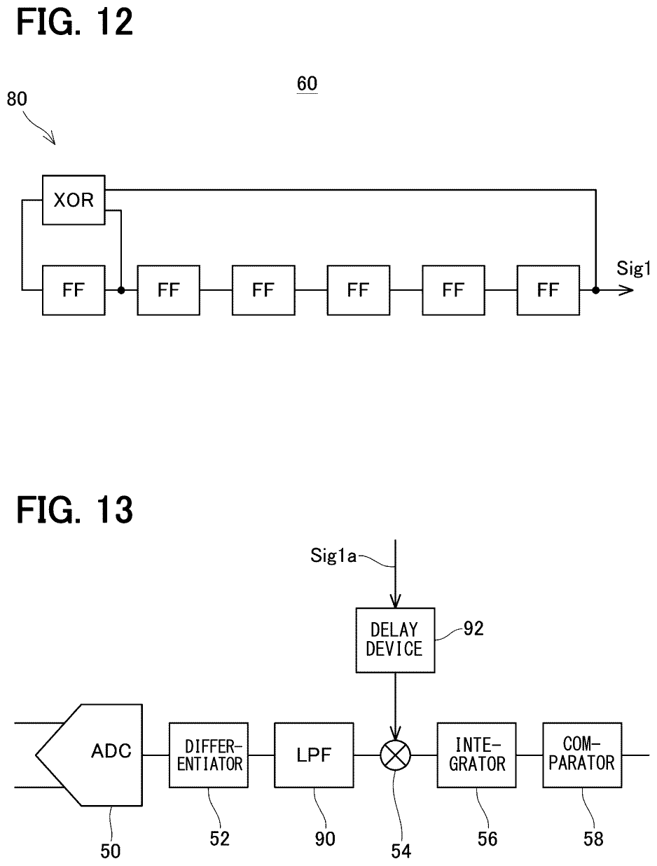

In the aforementioned first to sixth embodiments, the signal Sig1 has one or more frequency components. In contrast, in a seventh embodiment, the modulation signal generator 60 outputs a pulse signal that changes at random intervals as the signal Sig1. In the seventh embodiment, the modulation signal generator 60 is configured by a linear feedback shift register 80 (hereinafter referred to as LFSR 80) shown in FIG. 12. The LFSR 80 has six flip-flop circuits (hereinafter referred to as FF circuits) connected in series and an XOR circuit. The XOR circuit receives the output values of the first-stage FF circuit and the sixth-stage FF circuit as inputs. The output value of the XOR circuit is input to the first-stage FF circuit. The LFSR 80 outputs the output value of the sixth-stage FF circuit as the signal Sig1. According to this configuration, a pulse signal with a random period can be output as the signal Sig1. Even when using a random signal as the signal Sig1, it is possible to appropriately detect the disconnection. Additionally, when the signal Sig1 is a random signal, the erroneous detection of disconnection can be more effectively suppressed when the voltage Vs fluctuates.

In any embodiment, as shown in FIG. 13, a low-pass filter (hereinafter referred to as LPF) 90 may be provided between the differentiator 52 and the multiplier 54. In this case, the signal Sigla may be provided to the multiplier 54 via a delay device 92. The delay device 92 delays the signal Sigla and outputs it. The amount of delay of the signal in the delay device 92 is set to match the amount of delay of the signal generated by the ADC 50, the differentiator 52, and the LPF 90. Therefore, the two signals provided to the multiplier 54 can be accurately synchronized, allowing the voltage detection circuit to operate appropriately.

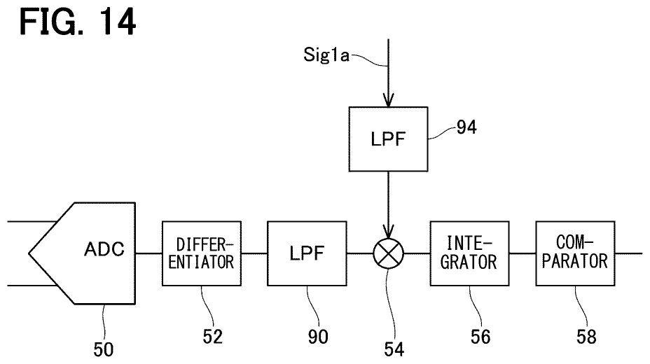

Also, as shown in FIG. 14, the signal Sigla may be input to the multiplier 54 via an LPF 94. The LPF 94 has filter characteristics that match the filter characteristics of the ADC 50, the differentiator 52, and the LPF 90. According to this configuration, errors due to differences in filter characteristics can be suppressed.

The frequency fc corresponds to a reference frequency. The frequencies fa and fb correspond to frequency components of the modulation signal. The chopper circuit 32 and DEM 36 correspond to selection circuits.

Although the embodiments have been described in detail above, these are merely examples and do not limit the scope of the present disclosure. The techniques described in the present disclosure include various modifications and modifications of the specific examples illustrated above. The technical elements described in the present disclosure or the drawings exhibit technical usefulness alone or in various combinations, and are not limited to the combinations described in the claims at the time of filing. In addition, the techniques illustrated in the present specification or drawings achieve multiple objectives at the same time, and achieving one of the objectives itself has technical usefulness.

What is claimed is:

1. A voltage detection circuit comprising:
a modulation signal generator configured to generate a modulation signal;
an AD converter configured to convert a voltage applied between a first input wiring and a second input wiring into a digital value;
a current source configured to
supply a first current to the first input wiring, the first current varying based on the modulation signal, and
supply a second current to the second input wiring, the second current varying based on the modulation signal;
a differentiator configured to output a value acquired by differentiating an output value of the AD converter;
a multiplier configured to multiply an output value of the differentiator by a value that varies positively and negatively according to the modulation signal; and
an integrator configured to integrate an output value of the multiplier.

2. The voltage detection circuit according to claim 1, wherein
the modulation signal varies at a reference frequency.

3. The voltage detection circuit according to claim 1, wherein
the modulation signal has frequency components.

4. The voltage detection circuit according to claim 1, wherein
the current source includes:
a first DA converter configured to convert the modulation signal into the first current; and
a second DA converter configured to convert the modulation signal into the second current.

5. The voltage detection circuit according to claim 1, further comprising:
a current generation circuit configured to:
draw a current from the first input wiring in a period during which supply of the first current is stopped; and
draw a current from the second input wiring in a period during which supply of the second current is stopped.

6. The voltage detection circuit according to claim 1, wherein
the current source includes:
a first constant current source;
a second constant current source; and
a chopper circuit configured to execute switchover between a first connection state and a second connection state,
the first connection state being a state in which
a current from the first constant current source is supplied as the first current to the first input wiring, and
a current from the second constant current source is supplied as the second current to the second input wiring,
the second connection state being a state in which
a current from the second constant current source is supplied as the first current to the first input wiring, and
a current from the first constant current source is supplied as the second current to the second input wiring, wherein
a frequency at which the switchover is executed by the chopper circuit is a multiple of a sampling frequency of the AD converter by an integer factor.

7. The voltage detection circuit according to claim 1, wherein
the current source includes:
constant current sources;
a selection circuit configured to
select at least one of the constant current sources as a first constant current source, and
select at least another one of the constant current sources as a second constant current source;
a first current generation circuit configured to generate the first current based on a current supplied from the first constant current source; and
a second current generation circuit configured to generate the second current based on a current supplied from the second constant current source, wherein
the selection circuit is configured to change, over time, combination of the first constant current source and the second constant current source, selected from the constant current sources.
